(19) United States
(12) Patent Application Publication
(10) Pub. No.: US 2024/0346197 A1
(43) Pub. Date: Oct. 17, 2024

(54) METHOD AND SYSTEM FOR GENERATING FUNCTIONAL CHAINS OF TEST DEVICES OF VEHICLES IN SIMULATION ENVIRONMENTS

(71) Applicant: L&T TECHNOLOGY SERVICES LIMITED, Chennai (IN)

(72) Inventors: SUSHANTA KUMAR SARKAR, Bengaluru (IN); JAGYAN PRAKASH MISHRA, Bengaluru (IN); PRABHAT SHRIVASTAV, Mysore (IN)

(21) Appl. No.: 18/749,652

(22) Filed: Jun. 21, 2024

(30) Foreign Application Priority Data
Mar. 21, 2023 (IN) 202441022018

(51) Int. Cl. G06F 30/15

(52) U.S. Cl. CPC G06F 30/15

(57) ABSTRACT

A method and system of generating functional chains of test devices of vehicles in simulation environments, is disclosed. A processor receives a natural language input and a set of functional executable elements of a set of test devices corresponding to a functionality of a vehicle from a user device. One or more input ports, one or more output ports, and a set of dependencies are determined for each of the set of functional executable elements from a plurality of dependencies stored in a database based on the natural language input, using a Large Language Model (LLM). A functional chain is generated of the set of functional executable elements based on the one or more input ports, the one or more output ports, and the set of dependencies.

### TECHNICAL FIELD

This disclosure relates generally to vehicle testing and more particularly to a method and system of generating functional chains of test devices of vehicles in simulation environments.

### BACKGROUND

Modern vehicles are equipped with a combination of mechanical, electrical, and electronic components, including embedded software and algorithms in microcontrollers or processors that execute various tasks (i.e., functionalities) through one or more components of the vehicles. For example, Automatic Emergency Braking (AEB) and Auto Pilot in Advanced Driver Assistance Systems (ADAS) and Advanced Rider Assistance Systems (ARAS) of the vehicles. Such functionalities are executed in a vehicle through one or more components, such as brakes, engines, and steering. Execution of these functionalities involves a three-step process: sensing the environment of the vehicle, planning actions/response, and actuating the one or more components to implement the actions.

Currently, the vehicle functionalities (e.g., ADAS functionalities) are primarily validated with manual intervention (Hardware in the Loop, Vehicle Testing etc). The present state of art lacks a scalable simulation framework readily available off the shelves for end-to-end functionality validation of multiple OEM (Original Equipment Manufacturer) ADAS functionalities. The complexity of developing and testing the vehicle functionalities necessitates an advanced and standardized simulation environment to address the diverse combinations of electrical and electronic components used by different vehicle manufacturers. The absence of a standardized simulation environment in the present state of art complicates the testing and validation process for features like Auto Pilot or AEB. Presently, to test these functionalities, a manual process involving the connection of necessary Devices Under Test (DUTs), cross-compilation in various Operating Systems (e.g., Windows/Linux/QnX), and utilization of simulation environments (Carmaker/Carla/VTD) is required. The challenge is further magnified as different vehicle manufacturers employ unique mechanical designs, electrical drive, and control systems, and a variety of electrical components from different suppliers. Hence, simulation configuration and parameters that work for one manufacturer may not work for another manufacturer. In other words, the conventional simulation environments are not device/technology agnostic.

Therefore, there is a requirement for an integrated and adaptable methodology for generating functional chains of test devices of vehicles in simulation environments.

### SUMMARY OF THE INVENTION

In an embodiment, a method for generating functional chains of test devices of vehicles in simulation environments is disclosed. The method may include receiving, by a processor, a natural language input and a set of functional executable elements of a set of test devices corresponding to a functionality of a vehicle from a user device. In an embodiment, the natural language input may include information corresponding to the set of test devices. The method may further include determining, by the processor and for each of the set of functional executable elements, one or more input ports, one or more output ports, and a set of dependencies from a plurality of dependencies stored in a database based on the natural language input, using a Large Language Model (LLM). The method may further include generating, by the processor, a functional chain of the set of functional executable elements based on the one or more input ports, the one or more output ports, and the set of dependencies. In an embodiment, the functional chain may include the set of functional executable elements connected through the one or more input ports and the one or more output ports.

In another embodiment, a vehicle is disclosed. The vehicle may include a set of test devices, a processor coupled with the set of test devices, and a memory communicably coupled to the processor. The memory may store processor-executable instructions, which when executed by the processor, may cause the processor to receive a natural language input and a set of functional executable elements of the set of test devices corresponding to a functionality from a user device. In an embodiment, the natural language input may include information corresponding to the set of tests devices. The processor-executable instructions, on execution, may further cause the processor to determine one or more input ports, one or more output ports, and a set of dependencies for each of the set of functional executable elements from a plurality of dependencies stored in a database based on the natural language input, using an LLM. The processor-executable instructions, on execution, may further cause the processor to generate a functional chain of the set of functional executable elements based on the one or more input ports, the one or more output ports, and the set of dependencies. In an embodiment, the functional chain may include the set of functional executable elements connected through the one or more input ports and the one or more output ports.

In another embodiment, a system for generating functional chains of test devices of vehicles in simulation environments is disclosed. The system may include a processor and a memory coupled to the processor. The memory may store processor-executable instructions, which, on execution, may cause the processor to receive a natural language input and a set of functional executable elements of a set of test devices corresponding to a functionality from a user device. The natural language input may include information corresponding to the set of tests devices. For each of the set of functional executable elements, the processor-executable instructions, on execution, may further cause the processor to determine one or more input ports, one or more output ports, and a set of dependencies from a plurality of dependencies stored in a database based on the natural language input, using an LLM. The processor-executable instructions, on execution, may further cause the processor to generate a functional chain of the set of functional executable elements based on the one or more input ports, the one or more output ports, and the set of dependencies. The functional chain may include the set of functional executable elements connected through the one or more input ports and the one or more output ports.

It is to be understood that both the foregoing general description and the following detailed description are exemplary and explanatory only and are not restrictive of the invention, as claimed.

### BRIEF DESCRIPTION OF THE DRAWING

The accompanying drawings, which are incorporated in and constitute a part of this disclosure, illustrate exemplary embodiments and, together with the description, serve to explain the disclosed principles.

FIG. 1 illustrates a block diagram of an exemplary functional chain generation system for generating functional chains of test devices of vehicles, in accordance with an embodiment of the present disclosure.

FIG. 2 illustrates a functional block diagram of a computing device, in accordance with an embodiment of the present disclosure.

FIG. 3 illustrates a flowchart of a method of generating functional chains of test devices of vehicles in simulation environments, in accordance with an embodiment of present disclosure.

FIG. 4A illustrates a schematic diagram representing generation of functional chains of test devices of vehicles using an offline LLM, in accordance with an embodiment of present disclosure.

FIG. 4B illustrates a schematic diagram representing generation of functional chains of test devices of vehicles using an online LLM, in accordance with an embodiment of present disclosure.

FIG. 5A illustrates a table representing exemplary training data of a sensing interface, in accordance with an embodiment of present disclosure.

FIG. 5B illustrates a table representing exemplary training data of a thinking interface, in accordance with an embodiment of present disclosure.

FIG. 5C illustrates a table representing exemplary training data of an actuator interface, in accordance with an embodiment of present disclosure.

FIG. 6 illustrates an exemplary scenario of a test case execution in a simulation environment, in accordance with an embodiment of present disclosure.

### DETAILED DESCRIPTION OF THE DRAWINGS

Exemplary embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the scope of the disclosed embodiments. It is intended that the following detailed description be considered exemplary only, with the true scope being indicated by the following claims. Additional illustrative embodiments are listed.

Further, the phrases “in some embodiments”, “in accordance with some embodiments”, “in the embodiments shown”, “in other embodiments”, and the like mean a particular feature, structure, or characteristic following the phrase is included in at least one embodiment of the present disclosure and may be included in more than one embodiment. In addition, such phrases do not necessarily refer to the same embodiments or different embodiments. It is intended that the following detailed description be considered exemplary only, with the true scope being indicated by the following claims.

In the whole automotive product development cycle, virtualization is essential at multiple levels, ranging from the open-world scenario layer to the control unit layer within the vehicle. The virtualization needs of all the system layers of automotive product development cycle across various aspects of automotive development, including the open-world environment, the vehicle itself and the Advanced Driver Assistance Systems (ADAS) or Advanced Rider Assistance Systems (ARAS). In open world layer, virtualization allows for the creation of realistic open-world scenarios in a simulated environment. This is crucial for testing and validating vehicle performance in diverse conditions, such as different weather conditions, road types, traffic scenarios, and test for infinite duration/billions of miles.

In vehicle world layer, virtualization enables the creation of hardware-in-the-loop (HiL) testing. This involves connecting virtual vehicle components, including control units, sensors, and actuators, to a simulated environment. HiL testing helps validate the functionality and performance of the electronic systems of the vehicle before physical prototype are available. In control unit testing layer, virtualization supports software development for control units by providing a simulated environment for testing and integration. It allows us to work on control unit software and algorithms in a virtual space, reducing the reliance on physical prototype. In ADAS testing layer, virtualization supports the testing of ADAS functionalities, such as sensor fusion and perception algorithms. Simulated sensor data can be used to access the system's ability to interpret and respond to the environment accurately. Furthermore, virtualization supports the development and testing of autonomous driving algorithms. Simulated scenarios enable thorough testing of ADAS features, including lane-keeping, automatic emergency braking, and adaptive cruise control, in a controlled environment before real world deployment.

The evaluation and validation of software components in a simulated or virtual environment, typically conducted after the delivery of the software. The concept of Software in Loop (SIL) testing involves the evaluation and validation of software components in a simulated or virtual environment, typically conducted after the delivery of the software. The challenges faced in the industry related to SIL, as SIL tools are intricately connected, either directly or indirectly, to the software under test. Achieving SIL first or front-loading the development process is challenging within the current automotive development cycle. This is due to the intricate dependencies and complexities involved in synchronizing the SIL testing tools with the ongoing development activities. The nature of SIL-based test platforms often presents difficulties in terms of usability, updates, and modifications. This challenge contributes to a less-than-optimal user experience, limiting the acceptance of SIL testing methodologies, particularly in comparison to industries like aviation where SIL approaches have found more widespread adoption. The aviation industry's success in incorporating SIL testing may stem from established practices and robust tooling, highlighting the need for advancements and improvements in SIL testing platforms for broader acceptance in the automotive sector.

The ADAS of the automotive development cycle are divided into three parts such as sensing, computing, and actuation. The actuation part involves devices such as the engine, steering, and brakes, each having its own controller. The primary devices in the actuation part include powertrain module (engine or electric machine), steering, and brakes are sufficient for vehicle movement in different modes (manual, partially autonomous, fully autonomous. The sensing part involves various sensors including cameras, radar, LIDAR, etc. are for environmental sensing. The selection of sensors is dependent on the Original Equipment Manufacturer (OEM) and their intended features. The computing part is responsible for tasks like trajectory planning, finding free space, etc.

Accordingly, the present disclosure provides an adaptive, intelligent, scalable advanced simulation platform capable of fulfilling the virtualization needs of all the system layers of automotive product development cycle. It is to be noted that the system may be employed in any vehicle or may be a standalone system. In an embodiment, examples of the vehicle may include, but is not limited to, a passenger vehicle, a utility vehicle, a commercial vehicle, and any other transportable machinery. The vehicle may be configured to operate on one or more of road, rail, on or beneath water surface, in the air, or in outer space environments. The vehicle may be a two-wheeler vehicle, a three-wheeler vehicle, a four-wheeler vehicle, or the like.

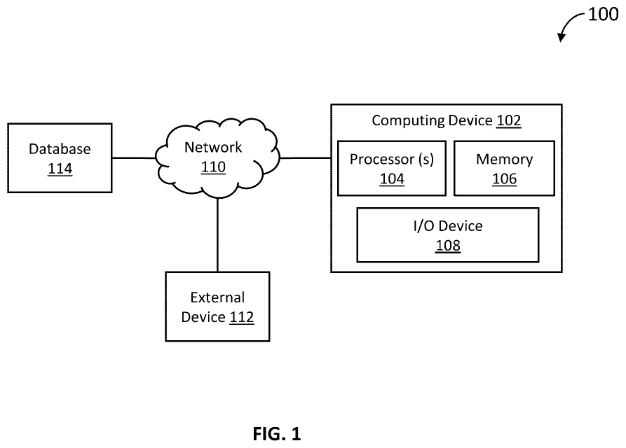

Referring now to FIG. 1, a block diagram of an exemplary functional chain generation system 100 for generating functional chains of test devices of vehicles is illustrated, in accordance with an embodiment of the present disclosure. The functional chain generation system 100 may include a computing device 102, an external device 112, and a database 114 communicably coupled to each other through a wired or wireless communication network 110. The computing device 102 may include a processor 104, a memory 106, and input/output (I/O) devices 108.

In an embodiment, examples of processor(s) 104 may include, but are not limited to, an Intel® Itanium® or Itanium 2 processor(s), or AMD® Opteron® or Athlon MP® processor(s), Motorola® lines of processors, Nvidia®, FortiSOC™ system on a chip processors or other processors that can be used to execute similar functions.

In an embodiment, the memory 106 may store instructions that, when executed by the processor 104, may cause the processor 104 to generate functional chains of test devices of vehicles in simulation environments, as discussed in more detail below. In an embodiment, the memory 106 may be a non-volatile memory or a volatile memory. Examples of non-volatile memory may include, but are not limited to, a flash memory, a Read Only Memory (ROM), a Programmable ROM (PROM), Erasable PROM (EPROM), and Electrically EPROM (EEPROM) memory. Further, examples of volatile memory may include, but are not limited to, Dynamic Random Access Memory (DRAM), and Static Random-Access memory (SRAM).

In an embodiment, the I/O devices 108 may include variety of interface(s), for example, interfaces for data input and output devices, and the like. The I/O devices 108 may facilitate inputting of instructions to the computing device 102 by a user. In an embodiment, the I/O devices 108 may be wirelessly connected to the computing device 102 through wireless network interfaces such as Bluetooth®, infrared, Wi-Fi, or any other wireless communication technology known in the art. In an embodiment, the I/O devices 108 may be connected to a communication pathway for one or more components of the computing device 102 to facilitate the transmission of inputted instructions and output results of data generated by various components such as, but not limited to, processor(s) 104 and memory 106.

In an embodiment, the database 114 may be enabled in a cloud or may be a physical database. The database 114 may store contextual data and training dataset. In an embodiment, the training dataset may include data that may be used to train various Large Language Model (LLM) models. In an embodiment, the database 114 may store data input by an external device 112 or output generated by the computing device 102.

In an embodiment, the communication network 110 may be a wired or a wireless network or a combination thereof. The network 110 can be implemented as one of the different types of networks, such as but not limited to, ethernet IP network, intranet, local area network (LAN), wide area network (WAN), the internet, Wi-Fi, LTE network, CDMA network, 5G and the like. Further, the network 110 can either be a dedicated network or a shared network. The shared network represents an association of the different types of networks that use a variety of protocols, for example, Hypertext Transfer Protocol (HTTP), Transmission Control Protocol/Internet Protocol (TCP/IP), Wireless Application Protocol (WAP), and the like, to communicate with one another. Further the network 110 can include a variety of network devices, including routers, bridges, servers, computing devices, storage devices, and the like.

In an embodiment, the computing device 102 may receive a request to generate functional chains of test devices of vehicles in simulation environments from an external device 112 through the network 110. In an embodiment, the computing device 102 and the external device 112 may be a computing system, including but not limited to, a smart phone, a laptop computer, a desktop computer, a notebook, a workstation, a portable computer, a handheld, a scanner, or a mobile device. In an embodiment, the computing device 102 may be, but not limited to, in-built into the external device 112 or may be a standalone computing device.

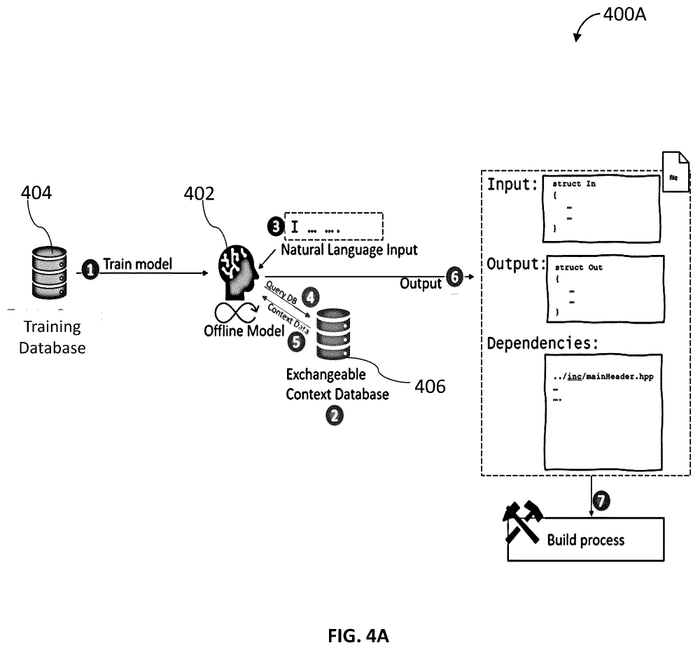

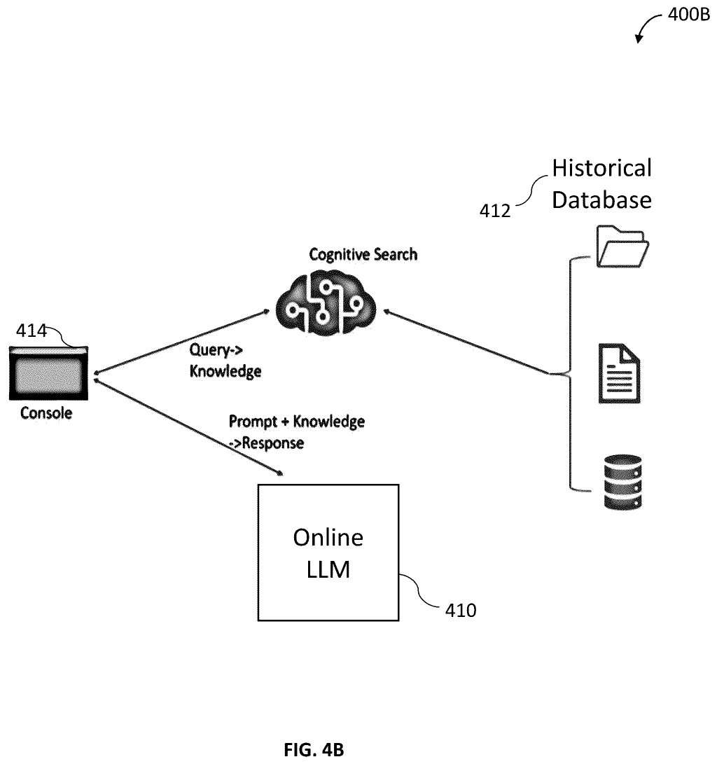

In an embodiment, the computing device 102 may perform various processing in order to generate functional chains of test devices of vehicles in simulation environments. The computing device 102 may implement a simulation environment. In an embodiment, the computing device 102 may receive a natural language input and a set of functional executable elements of a set of test devices corresponding to a functionality of a vehicle from a user device. A GUI of the simulation environment may be rendered on the user device, allowing a user to input the set of functional executable elements required to simulate the functionality. By way of an example, the functionality may be braking, steering, propulsion/engine, or the like. A functional executable element may correspond to a Device Under Test (DUT) which is a functional element written in any standard programming language (C, C++, Python or any other) compiled to run/execute on the simulation target platform. A DUT may be a software component that may be used to control a corresponding test device. In some embodiments, a combination of one or more DUTs may be used in the simulation environment to simulate the end-to-end functionality. For example, a combination of two DUTs may be used to simulate braking functionality by working with one or more actuators corresponding to braking test devices. In an embodiment, the set of functional executable elements may be drag and dropped to the build environment (FIG. 4A, 7) to create functional executable elements that are selectable and configurable by the user.

In an embodiment, the natural language input may include information corresponding to the set of test devices. In an embodiment, the natural language input may be a real-time input from a user. In an embodiment, a format of the natural language input may be provided as a file with a file format of a Portable Document Format (PDF), a Joint Photographic Experts Group (JPEG), a voice note, an Excel sheet, a Word document, etc.

Further, the computing device 102 may extract contextual data corresponding to the natural language input from an exchangeable context database. In an embodiment, the computing device 102 may use a Retrieval Augmented Generation (RAG) technique to extract the contextual data. In an embodiment, the contextual data may include domain technology information and equipment information of the vehicle manufacturer.

Further, the computing device 102 may determine one or more input ports, one or more output ports, and a set of dependencies from a plurality of dependencies stored in a database based on the natural language input, and the contextual data using an LLM. In an embodiment, the LLM may be an offline LLM or an online LLM. In an embodiment the database may be a historical database. In an embodiment, the historical database may store training dataset. In an exemplary embodiment, the training dataset may include, but is not limited to, specification of each sensor and subcomponent of the vehicle which needs to be tested. In an embodiment example of the LLM may include, but is not limited to, Bidirectional Encoder Representations from Transformers (BERT), Generative Pre-trained Transformer (GPT), Pathways Language Model (PaLM), Gemini, Large Language Model Meta AI (LLaMA), etc.

Further, the computing device 102 may generate a functional chain of the set of functional executable elements based on the one or more input ports, the one or more output ports, and the set of dependencies. In an embodiment, the functional chain may include the set of functional executable elements connected through the one or more input ports and the one or more output ports. For example, in a function chain including 3 DUTs (e.g., a first DUT, a second DUT, and a third DUT), an output port of the first DUT may be connected (i.e., wired) to an input port of the second DUT. An output port of the second DUT may be connected to an input port of the third DUT.

Further, the computing device 102 may integrate the functional chain with one or more additional components (e.g., camera, sensors, actuators, etc.) corresponding to the functionality to obtain an integrated simulation model in the simulation environment. The one or more additional components may be simulation components or physical devices. In an embodiment, examples of the simulation environment may include, but are not limited to, AirSim, Gazebo, LGSVL simulator, rFpro, Carla, etc.

Further, the computing device 102 may execute a test case using the integrated simulation model. For example, the test case may correspond to various scenarios for testing the functionalities of ADAS of the vehicle. In some embodiments, the computing device 102 may generate a report that may include results of the execution of the test case. The computing device 102 may render a visualization of the execution of the test case on a user device via the GUI.

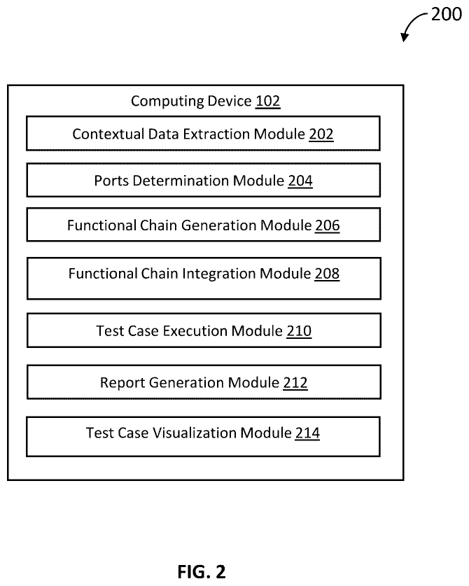

Referring now to FIG. 2, a functional block diagram of the computing device 102 is illustrated, in accordance with an embodiment of the present disclosure. In an embodiment, the computing device 102 may include a contextual data extraction module 202, a ports determination module 204, a functional chain generation module 206, a functional chain integration module 208, a test case execution module 210, a report generation module 212, a test case visualization module 214.

The computing device 102 may receive a natural language input and a set of functional executable elements of a set of test devices corresponding to a functionality of a vehicle from a user device. In an embodiment, the set of functional executable elements may include, but are not limited to, drag and drop functional executable elements of the set of test devices corresponding to the functionality of the vehicle. In an embodiment, the functionality may include but is not limited to, braking, propulsion, and steering, etc. In an embodiment, the natural language input may include information corresponding to the set of test devices. In an embodiment, the natural language input may be a real-time input from a user. In an embodiment, a format of the natural language input may include, but is not limited to a Portable Document Format (PDF), a Joint Photographic Experts Group (JPEG), a voice note, a excel sheet, a word document, etc.

The contextual data extraction module 202 may extract contextual data corresponding to the natural language input from an exchangeable context database. In an embodiment, the contextual data may include domain information. In an embodiment, the exchangeable context database may be updated based on contextual data by the user.

Further, the ports determination module 204 may determine one or more input ports, one or more output ports, and a set of dependencies from a plurality of dependencies stored in a database based on the natural language input, and the contextual data using a Large Language Model (LLM). In an embodiment, the LLM may be an offline LLM or an online LLM. In an embodiment the database may be a historical database. In an embodiment, the historical database may store training dataset. In an exemplary embodiment, the training dataset may include, but is not limited to, specification of each sensor and subcomponent of the vehicle which needs to be tested. In an embodiment example of the LLM model may include but is not limited to (Bidirectional Encoder Representations from Transformers) BERT, (Generative Pre-trained Transformer) GPT, etc.

Further, the functional chain generation module 206 may generate a functional chain of the set of functional executable elements based on the one or more input ports, the one or more output ports, and the set of dependencies. In an embodiment, the functional chain may include the set of functional executable elements connected through the one or more additional components corresponding to the functionality to obtain an integrated simulation model in a simulation environment.

Further, the functional chain integration module 208 may integrate the functional chain with one or more additional components corresponding to the functionality to obtain an integrated simulation model in a simulation environment. In an embodiment, examples of the simulation environment may include, but are not limited to, AirSim, Gazebo, LGSVL simulator, rFpro, Carla, etc.

Further, the test case execution module 210 may execute a test case using the integrated simulation model. Further, the report generation module 212 may generate a report that may include results of the execution of the test case. Further, the test case visualization module 214 may render a visualization of the execution of the test case on a user device via a GUI.

It should be noted that all such aforementioned modules 202-214 may be represented as a single module or a combination of different modules. Further, as will be appreciated by those skilled in the art, each of the modules 202-214 may reside, in whole or in parts, on one device or multiple devices in communication with each other. In some embodiments, each of the modules 202-214 may be implemented as dedicated hardware circuit comprising custom application-specific integrated circuit (ASIC) or gate arrays, off-the-shelf semiconductors such as logic chips, transistors, or other discrete components. Each of the modules 202-214 may also be implemented in a programmable hardware device such as a field programmable gate array (FGPA), programmable array logic, programmable logic device, and so forth. Alternatively, each of the modules 202-214 may be implemented in software for execution by various types of processors (e.g. processor 104). An identified module of executable code may, for instance, include one or more physical or logical blocks of computer instructions, which may, for instance, be organized as an object, procedure, function, or other construct. Nevertheless, the executables of an identified module or component need not be physically located together but may include disparate instructions stored in different locations which, when joined logically together, include the module and achieve the stated purpose of the module. Indeed, a module of executable code could be a single instruction, or many instructions, and may even be distributed over several different code segments, among different applications, and across several memory devices.

As will be appreciated by one skilled in the art, a variety of processes may be employed for generating functional chains of test devices of vehicles in simulation environments. For example, the exemplary system 100 and the associated computing device 102 may generate functional chains of test devices of a vehicle by the processes discussed herein. In particular, as will be appreciated by those of ordinary skill in the art, control logic and/or automated routines for performing the techniques and steps described herein may be implemented by the system 100 and the associated computing device 102 either by hardware, software, or combinations of hardware and software. For example, suitable code may be accessed and executed by the one or more processors on the system 100 to perform some or all of the techniques described herein. Similarly, application specific integrated circuits (ASICs) configured to perform some, or all of the processes described herein may be included in the one or more processors on the system 100.

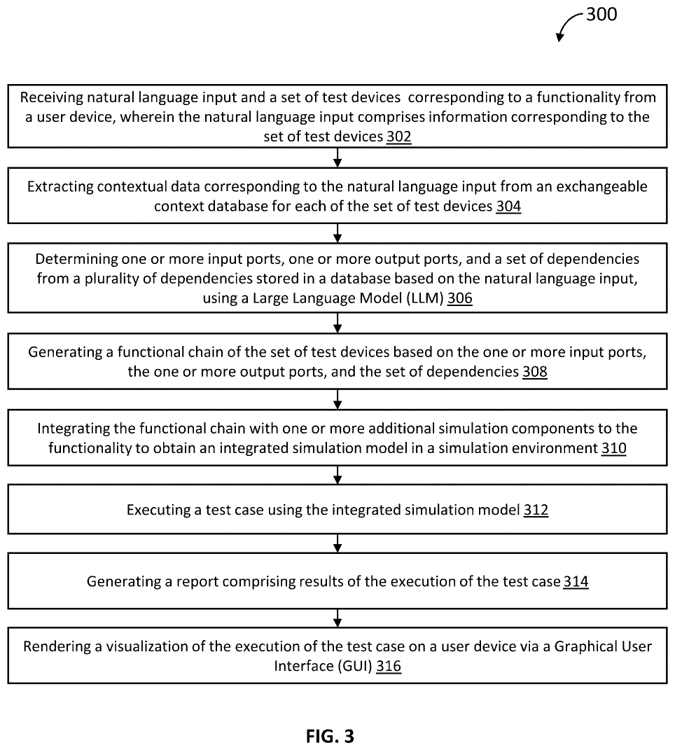

Referring now to FIG. 3, a flow diagram of a method 300 of generating functional chains of test devices of vehicles in simulation environments is illustrated, in accordance with an embodiment of present disclosure. In an embodiment, method 300 may include a plurality of steps that may be performed by the processor 104 to generate functional chains of test devices of vehicles.

FIG. 3 is explained in conjunction with FIGS. 1 and 2. Each step of the method 300 may be executed by various modules of the computing device 102.

At step 302, a natural language input, a set of functional executable elements of a set of test devices corresponding to a functionality of a vehicle may be received by the computing device 102 from a user device. In an embodiment, the functional executable elements may include, but are not limited to, drag, and drop functional executable elements corresponding to each of the set of test devices of the vehicle. In an embodiment, the natural language input may include information corresponding to the set of test devices.

Further at step 304, contextual data corresponding to the natural language input may be extracted, by the contextual data extraction module 202, from an exchangeable context database. In an embodiment, the contextual data may include domain technology information.

Further at step 306, one or more input ports, one or more output ports, and a set of dependencies from a plurality of dependencies stored in a database may be determined, by the ports determination module 204, based on the natural language input, using a Large Language Model (LLM). In an embodiment, the LLM may be an offline LLM or an online LLM.

Further at step 308, a functional chain of the set of functional executable elements may be generated, by the functional chain generation module 206, based on the one or more input ports, the one or more output ports, and the set of dependencies. In an embodiment, the functional chain may include the set of functional executable elements connected through the one or more additional components corresponding to the functionality to obtain an integrated simulation model in a simulation environment.

Further at step 310, the functional chain may be integrated, by the functional chain integration module 208, with one or more additional components corresponding to the functionality to obtain an integrated simulation model in a simulation environment.

Further at step 312, a test case may be executed, by the test case execution module 210, using the integrated simulation model. Further at step 314, a report may be generated, by the report generation module 212, that may include results of the execution of the test case. Further at step 316, a visualization of the execution of the test case may be rendered, by the test case visualization module 214, on a user device via a GUI.

Referring now to FIG. 4A, a schematic diagram 400A representing generation of functional chains of test devices of vehicles using an offline LLM 402 is illustrated, in accordance with an embodiment of the present disclosure. FIG. 4A is explained in conjunction with FIGS. 1, 2, and 3.

In accordance with an embodiment of the present disclosure, an offline LLM 402 may be trained offline based on a training database 404 by a car manufacturer. The offline LLM 402 may be hosted locally (i.e., the data input to the offline 402 may be owned by the car manufacturer and/or any third party authorized by the car manufacturer). In an embodiment, the training database may store a training dataset. In an embodiment, the training dataset may include various test device parameters such as, but not limited to, a plurality of dependencies, a plurality of input ports, and a plurality of output ports.

Further, the offline LLM 402 may receive a natural language input and a set of functional executable elements of a set of devices corresponding to a functionality of a vehicle from a user device. In an embodiment, the functional executable elements may be drag and drop functional executable elements corresponding to each of the set of test devices of the vehicle. In an embodiment, the natural language input may include information corresponding to the set of test devices.

Further, the offline LLM 402 may extract contextual data corresponding to the natural language input from an exchangeable context database 406. In an embodiment, the contextual data may include domain technology information and test device information. It should be noted that the offline LLM 402 may be trained at an initial time. However, domain technology and test device features may evolve with time for which the offline LLM 402 may not have been trained. Thus, the exchangeable context database 406, which may be frequently updated with test device information by the car manufacturer, may provide contextual data corresponding to the natural language input to provide more relevant output data.

The offline LLM 402 may determine one or more input ports from the plurality of input ports, one or more output ports from the plurality of output ports, and a set of dependencies from the plurality of dependencies stored in the training database 404 based on the natural language input, and the contextual data.

Further, the computing device 102 may generate a functional chain of the set of functional executable elements based on the one or more input ports, the one or more output ports, the one or more output ports, and the set of dependencies.

Referring now to FIG. 4B, a schematic diagram 400B representing generation of functional chains of test devices of vehicles using an online LLM 410 is illustrated, in accordance with and embodiment of present disclosure. FIG. 4B is explained in conjunction with FIGS. 1, 2, 3, and 4A.

In accordance with an embodiment of the present disclosure, the online LLM 410 may be trained online on a cloud based on a historical database 412 and the online LLM 410 may be hosted on a server that may be accessible to one or more car manufacturers. In an embodiment, the online LLM 410 may receive a natural language input and a set of functional executable elements of a set of devices corresponding to a functionality of a vehicle from a user device via the console 414. The online LLM 410 may not require an exchangeable contextual database like the offline LLM 402 as it may be updated with domain technology information and test device information in real-time. In an embodiment, the functional executable elements may include, but are not limited to, drag, and dropped to the build environment (FIG. 4A, 7) to create functional executable elements corresponding to each of the set of test devices of the vehicle. In an embodiment, the natural language input may include information corresponding to the set of test devices.

In an embodiment, the historical database 412 may store historical data, a plurality of dependencies, a plurality of input ports, and a plurality of output ports. In an embodiment, the historical data may include domain technology information. In an embodiment, the natural language input may be a real-time input from a user.

The online LLM 410 may further determine one or more input ports, one or more output ports, and a set of dependencies from a plurality of dependencies stored in the historical database 412 by querying the online LLM 410 based on the natural language input to determine the one or more input ports, the one or more output ports, and the set of dependencies.

Further, the computing device 102 may generate a functional chain of the set of functional executable elements based on the one or more input ports, the one or more output ports, the one or more output ports, and the set of dependencies.

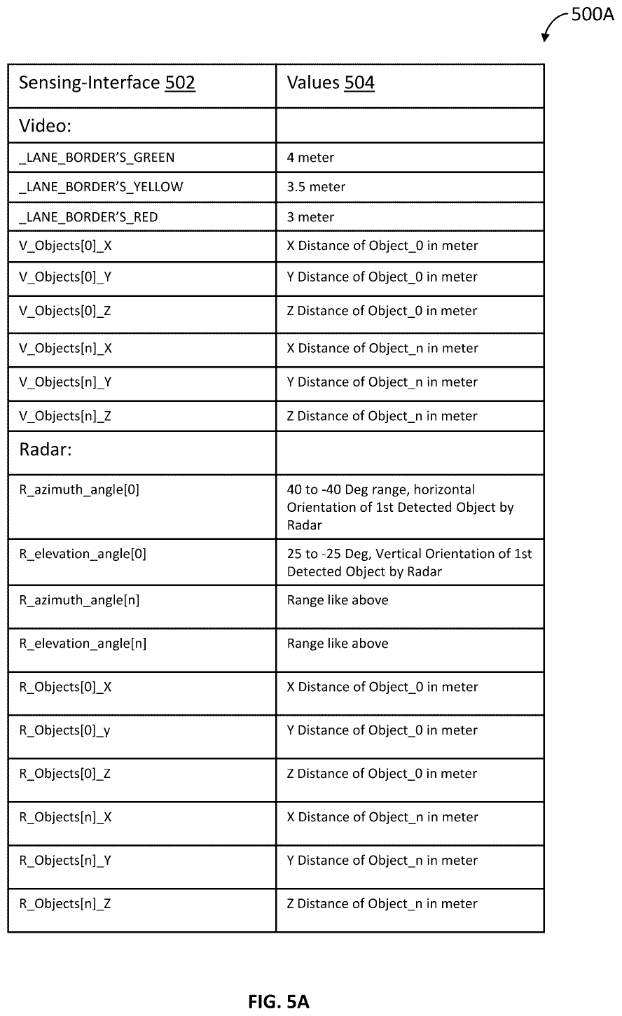

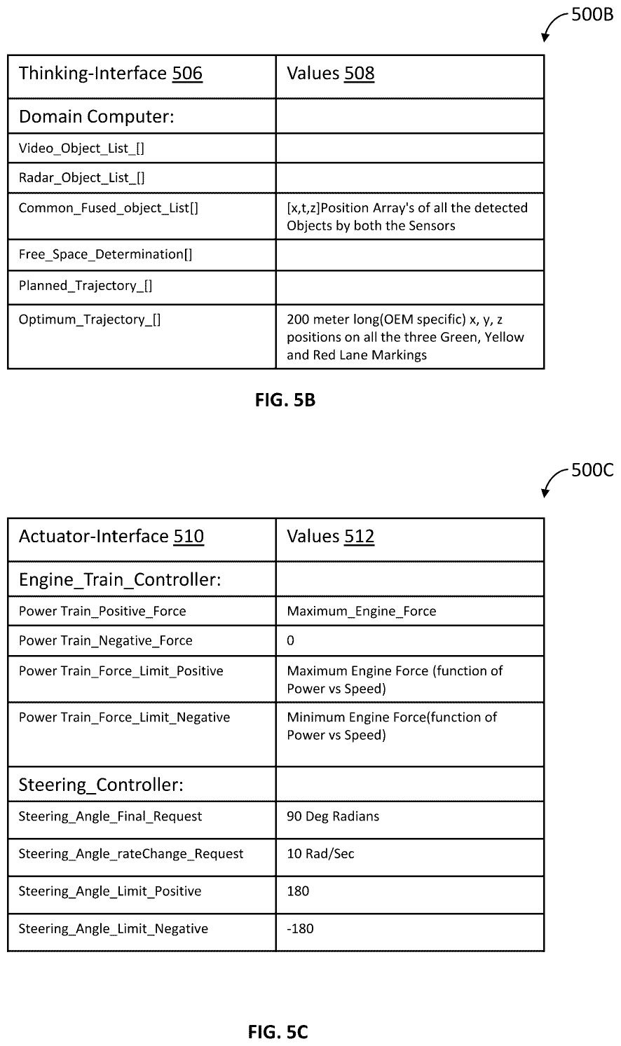

Referring now to FIG. 5A, a table 500A representing exemplary training data of a sensing interface is illustrated, in accordance with an embodiment of the present disclosure. FIG. 5A is explained in conjunction with FIGS. 1, 2, 3, and 4A-B. The table 500A may include a plurality of columns. The plurality of columns may include a sensing interface column 502, and a values column 504. The sensing interface column 502 may include one or more input ports and one or more output ports corresponding to a video sensing and radar sensing functionality of a vehicle. The values column 504 may include a corresponding value to each of the video and radar functionality of the vehicle.

Referring now to FIG. 5B, a table 500B representing exemplary training data of a thinking interface is illustrated, in accordance with an embodiment of the present disclosure. FIG. 5B is explained in conjunction with FIGS. 1, 2, 3, 4A-B, and 5A. The table 500B may include a plurality of columns. The plurality of columns may include a thinking-interface column 506, and a values column 508. The thinking-interface column 506 may include one or more input ports and one or more output ports corresponding to a computer domain thinking functionality of a vehicle. The values column 508 may include a corresponding value to each of the computer domain thinking functionality of the vehicle.

Referring now to FIG. 5C, a table 500C representing exemplary training data of an actuator interface is illustrated, in accordance with an embodiment of the present disclosure. FIG. 5C is explained in conjunction with FIGS. 1 and 2. The table 500C may include a plurality of columns. The plurality of columns may include an actuator interface column 510, and a values column 512. The actuator interface column 510 may include one or more input ports and one or more output ports corresponding to an engine train controller and a steering controller functionality of a vehicle. The values column 512 may include a corresponding value to each of the computer domain thinking functionality of the vehicle.

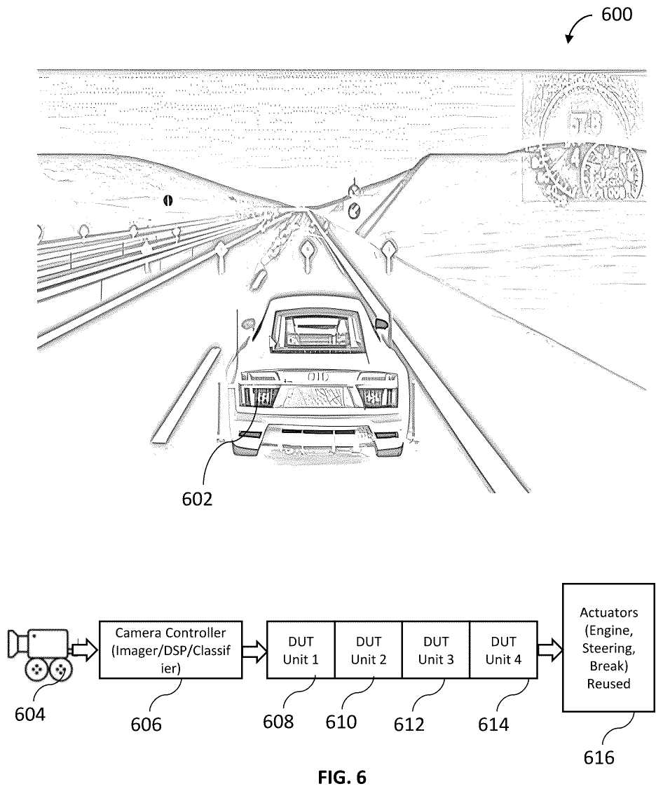

Referring now to FIG. 6, an exemplary scenario of a test case execution in a simulation environment 600 is illustrated, in accordance with an embodiment of the present disclosure. The simulation environment 600 may simulate the set of test devices of the vehicle 602. In accordance with an embodiment of the present disclosure, the simulation environment 600 may represent a video-based traffic sign recognition and speed limit function implemented in the vehicle 602. In an embodiment, a camera 604 may act as an environment sensor to sense the environment. The camera 604 may be actuated by a camera controller 606. In an embodiment, the camera controller 606 may be, but is not limited to, an imager, a digital signal processor, and a classifier, etc. In an embodiment, the computing device 102 may receive a natural language input and a set of functional executable elements 608, 610, 612, 614 of the set of test devices corresponding to a functionality of a vehicle from a user device.

Further, the computing device 102 may extract contextual data corresponding to the natural language input from an exchangeable context database. In an embodiment, the contextual data may include domain technology information.

Further, the computing device 102 may determine one or more input ports, one or more output ports, and a set of dependencies from a plurality of dependencies stored in a database based on the natural language input, and the contextual data using an LLM.

Further, the computing device 102 may generate a functional chain of the set of functional executable elements 608, 610, 612, 614 based on the one or more input ports, the one or more output ports, and the set of dependencies. In an embodiment, the functional chain may include the set of functional executable elements 608, 610, 612, 614 connected (i.e., wired) through the one or more input ports and the one or more output ports. By way of an example, the input port of the functional executable 608 is connected to the output port of the camera controller 606. The output port of the functional executable element 608 is connected to the input port of the functional executable element 610, and so on.

Further, the computing device 102 may integrate the functional chain with one or more additional components (for example, actuators 616) corresponding to the functionality to obtain an integrated simulation model in a simulation environment. The actuators 616 may be physical devices or simulation components. By way of an example, the actuators 616 may correspond to test devices related to engine, steering, braking, etc.

Further, the computing device 102 may execute a test case using the integrated simulation model. The execution may be based on output provided by the functional chain. The function chain may process the input data provided by a sensor (here the input data is provided by the camera 604) and generate an output that may include a response or an action to be executed by the actuators 616 of the vehicle 602.

Further, the computing device 102 may render a visualization of the execution of the test case on a user device via a GUI. Further, the computing device 102 may generate a report that may include results of the execution of the test case.

In accordance with an embodiment of the present disclosure, the results of the execution of the test case may be determined as 30 speed limits from traffic signal may be identified, and the vehicle 602 may follow the set speed limit using 1V sensor chain implementation.

Thus, the disclosed method and system tries to overcome the technical problem of building functional chains manually for testing the complexities of multiple test devices by a method and system of generating functional chains of test devices of vehicles in simulation environments against such challenges. In an embodiment, advantages of the disclosed method and system may include, but nay not be limited to, a fast and efficient verification and validation deployment, handle technology-heavy models, end-to-end method of building functional chains of test devices of vehicles automatically without manual intervention. The method and system provide a device and technology agnostic simulation platform that can be used for integrated end-to-end vehicle functionality testing. This is achieved by use of RAG-assisted LLM to give context-aware outputs to the user. The context-aware outputs enable efficient formation of complex functional chains for different car manufacturers, which previously had to be manually validated.

In light of the above-mentioned advantages and the technical advancements provided by the disclosed method and system, the claimed steps as discussed above are not routine, conventional, or well understood in the art, as the claimed steps enable the following solutions to the existing problems in conventional technologies. Further, the claimed steps bring an improvement in the functioning of the device itself as the claimed steps provide a technical solution to a technical problem.

The specification has described method and system for generating functional chains of test devices of vehicles in simulation environments. The illustrated steps are set out to explain the exemplary embodiments shown, and it should be anticipated that ongoing technological development will change the manner in which particular functions are performed. These examples are presented herein for purpose of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, non-volatile memory, hard drives, CD ROMs, DVDs, flash drives, disks, and any other known physical storage media.

It is intended that the disclosure and examples be considered as exemplary only, with a true scope of disclosed embodiments being indicated by the following claims.

What is claimed is:

1. A method of generating functional chains of test devices of vehicles in simulation environments, the method comprises:
receiving, by a processor, a natural language input and a set of functional executable elements of a set of test devices corresponding to a functionality of a vehicle from a user device, wherein the natural language input comprises information corresponding to the set of test devices;
for each of the set of functional executable elements, determining, by the processor, one or more input ports, one or more output ports, and a set of dependencies from a plurality of dependencies stored in a database based on the natural language input, using a Large Language Model (LLM); and
generating, by the processor, a functional chain of the set of functional executable elements based on the one or more input ports, the one or more output ports, and the set of dependencies, wherein the functional chain comprises the set of functional executable elements connected through the one or more input ports and the one or more output ports.

2. The method of claim 1, comprising:
integrating, by the processor, the functional chain with one or more additional components corresponding to the functionality to obtain an integrated simulation model in a simulation environment; and
executing, by the processor, a test case using the integrated simulation model.

3. The method of claim 1, comprising:
for each of the set of functional executable elements,
extracting, by the processor, contextual data corresponding to the natural language input from an exchangeable context database, wherein the contextual data comprises domain technology information; and
determining, by the processor, the one or more input ports, the one or more output ports, and the set of dependencies based on the natural language input and the contextual data, using the LLM, wherein the LLM is an offline LLM.

4. The method of claim 1, comprising generating, by the processor, a report comprising results of the execution of the test case.

5. The method of claim 1, comprising rendering, by the processor, a visualization of the execution of the test case on a user device via a GUI.

6. A vehicle, comprising:
a set of test devices;
a processor coupled with the set of test devices; and
a memory coupled to the processor, wherein the memory stores processor-executable instructions, which, on execution, cause the processor to:
receive a natural language input and a set of functional executable elements of the set of test devices corresponding to a functionality from a user device, wherein the natural language input comprises information corresponding to the set of tests devices;
for each of the set of functional executable elements, determine one or more input ports, one or more output ports, and a set of dependencies from a plurality of dependencies stored in a database based on the natural language input, using a Large Language Model (LLM); and
generate a functional chain of the set of functional executable elements based on the one or more input ports, the one or more output ports, and the set of dependencies, wherein the functional chain comprises the set of functional executable elements connected through the one or more input ports and the one or more output ports.

7. The vehicle of claim 6, wherein the processor-executable instructions, which, on execution, cause the processor) to:
integrate the functional chain with one or more additional simulation components corresponding to the functionality to obtain an integrated simulation model in a simulation environment; and
execute a test case using the integrated simulation model.

8. The vehicle of claim 6, wherein the processor-executable instructions, which, on execution, cause the processor to:
for each of the set of functional executable elements,
extract contextual data corresponding to the natural language input from an exchangeable context database, wherein the contextual data comprises domain technology information; and
determine the one or more input ports, the one or more output ports, and the set of dependencies based on the natural language input and the contextual data, using the LLM, wherein the LLM is an offline LLM.

9. The vehicle of claim 6, wherein the processor-executable instructions, which, on execution, cause the processor to render a visualization of the execution of the test case on a user device via a GUI.

10. The vehicle of claim 6, wherein the processor-executable instructions, which, on execution, cause the processor to generate a report comprising results of the execution of the test case.

11. A system for generating functional chains of test devices of vehicles in simulation environments, comprising:
a processor; and
a memory coupled to the processor, wherein the memory stores processor-executable instructions, which, on execution, cause the processor to:
receive a natural language input and a set of functional executable elements of a set of test devices corresponding to a functionality from a user device, wherein the natural language input comprises information corresponding to the set of tests devices;
for each of the set of functional executable elements, determine one or more input ports, one or more output ports, and a set of dependencies from a plurality of dependencies stored in a database based on the natural language input, using a Large Language Model (LLM); and
generate a functional chain of the set of functional executable elements based on the one or more input ports, the one or more output ports, and the set of dependencies, wherein the functional chain comprises the set of functional executable elements connected through the one or more input ports and the one or more output ports.

12. The system of claim 11, wherein the processor-executable instructions, which, on execution, cause the processor to:
integrate the functional chain with one or more additional simulation components corresponding to the functionality to obtain an integrated simulation model in a simulation environment; and
execute a test case using the integrated simulation model.

13. The system of claim 11, wherein the processor-executable instructions, which, on execution, cause the processor to:
for each of the set of functional executable elements,
extract contextual data corresponding to the natural language input from an exchangeable context database, wherein the contextual data comprises domain technology information; and
determine the one or more input ports, the one or more output ports, and the set of dependencies based on the natural language input and the contextual data, using the LLM, wherein the LLM is an offline LLM.

14. The system of claim 11, wherein the processor-executable instructions, which, on execution, cause the processor to render a visualization of the execution of the test case on a user device via a GUI.

15. The system of claim 11, wherein the processor-executable instructions, which, on execution, cause the processor to generate a report comprising results of the execution of the test case.
